(19) United States
(12) Patent Application Publication
(10) Pub. No.: US 2018/0034236 A1
(43) Pub. Date: Feb. 1, 2018

(54) BEAM SOURCE HAVING A LASER DIODE

(71) Applicant: OSRAM GmbH, Munich (DE)

(72) Inventor: Sergey Khrushchev, Regensburg (DE)

(21) Appl. No.: 15/658,439

(22) Filed: Jul. 25, 2017

(30) Foreign Application Priority Data
Jul. 28, 2016 (DE) 10 2016 213 902.9

(51) Int. Cl. H01S 5/022; G02B 27/09

(52) U.S. Cl. CPC H01S 5/02252; H01S 5/02288; G02B 27/0972

(57) ABSTRACT

A beam source includes a laser diode having an emission surface for emitting a divergent beam, a carrier structure on which the laser diode is arranged such that the beam has, immediately downstream of the emission surface, a direction component parallel to a surface of the carrier structure that faces the laser diode, and a reflection prism with a transparent prism material having a refractive index nₚ≧1.5. The diode and the prism are arranged relative to each other such that the beam from the diode is incident downstream on an entrance surface of the prism, travels through the prism material with a reduced aperture angle, and in the process is reflected away from the carrier structure at a reflection surface of the prism. The emission surface of the diode and the entrance surface of the prism have a distance from one another of at most 0.5 mm.

### CROSS-REFERENCE TO RELATED APPLICATION

This application claims priority to German Patent Application Serial No. 10 2016 213 902.9, which was filed Jul. 28, 2016, and is incorporated herein by reference in its entirety.

### TECHNICAL FIELD

Various embodiments relate generally to a beam source having a laser diode having an emission surface for emitting a divergent beam with laser radiation.

### BACKGROUND

A laser diode is a semiconductor component for generating laser radiation. The light is generated by recombination processes, and a standing wave can form in an optical resonator of the component. This region is also referred to as the “active zone”. The laser radiation is ultimately output at an emission surface of the laser diode in the form of a divergent beam.

### SUMMARY

A beam source includes a laser diode having an emission surface for emitting a divergent beam, a carrier structure on which the laser diode is arranged such that the beam has, immediately downstream of the emission surface, a direction component parallel to a surface of the carrier structure that faces the laser diode, and a reflection prism with a transparent prism material having a refractive index nₚ≧1.5. The diode and the prism are arranged relative to each other such that the beam from the diode is incident downstream on an entrance surface of the prism, travels through the prism material with a reduced aperture angle, and in the process is reflected away from the carrier structure at a reflection surface of the prism. The emission surface of the diode and the entrance surface of the prism have a distance from one another of at most 0.5 mm.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a first beam source according to various embodiments having a laser diode and a reflection prism in a schematic section illustration; and

FIG. 2 shows a second beam source according to various embodiments having a laser diode and a reflection prism in a schematic section illustration.

### DESCRIPTION

The following detailed description refers to the accompanying drawings that show, by way of illustration, specific details and embodiments in which the invention may be practiced.

Various embodiments provide a beam source having a laser diode.

According to various embodiments, a beam source is provided having a laser diode having an emission surface for emitting a divergent beam with laser radiation, a carrier structure on which the laser diode is arranged such that the beam has, immediately downstream of the emission surface, a direction component parallel to a surface of the carrier structure that faces the laser diode, and a reflection prism with a transparent prism material having a refractive index nₚ≧1.5, wherein the laser diode and the reflection prism are arranged relative to each other such that the beam from the laser diode is incident downstream on an entrance surface of the reflection prism, travels through the prism material with a reduced aperture angle, and in the process is reflected away from the carrier structure at a reflection surface of the reflection prism, and wherein the emission surface of the laser diode and the entrance surface of the reflection prism have a distance from one another of at most 0.5 mm.

Various embodiments can be gathered from the dependent claims and the entire disclosure, wherein a distinction is not always made in the summary specifically between apparatus and use aspects; in each case, the disclosure should be read implicitly with respect to all claim categories.

In the beam source according to various embodiments, the laser diode is initially arranged on the carrier structure such that the emitted beam propagates substantially parallel to the surface of the carrier structure. The beam is then deflected by way of the reflection prism such that it propagates away from the carrier structure, in this reference system toward the top. Without this change in direction, the divergent beam would in contrast either strike the carrier structure, i.e. be blocked thereby, or the laser diode would need to be located correspondingly closely to the periphery of the carrier structure, which in terms of assembly and also with respect to a stable construction can be disadvantageous. Arranged downstream of the beam source can be, for example, a lens, the positioning and configuration of which can be simplified in an arrangement above.

For the change in direction of the beam, a reflection prism is provided, wherein the prism material has a refractive index nₚ of at least 1.5, 1.6, 1.7, or 1.8, with increasing preference in the order of mention (refractive indexes considered within the context of this disclosure are generally at λ=450 nm). Possible upper limits can be, for example, 2 or 1.9. The reflection prism is preferably made of an optically dense glass, with an example being the type SF11 from Schott company or Type S-TIH53 from the manufacturer Ohara.

At the entrance surface of the reflection prism, the beam enters the higher-refractive prism material from a lower-refractive medium, upon which the aperture angle of the divergent beam becomes reduced. The lower-refractive medium between the laser diode and the reflection prism can also generally be, for example, air, e.g. an inert gas, or vacuum conditions may also be present, for example. Independently thereof, the reduction in the aperture angle in the reflection prism may be provided to the extent that it is thus possible to optimally utilize the limited installation space.

The reflection prism does not only cause a deflection, but internally also a reduction in the aperture angle, with the result that the beam takes up less space in the reversal of the direction. In addition, the beam here has, despite a possible broadening at the exit surface of the reflection prism, a lower cross section than would be the case for a reflection without a prism within the same reference plane. In summary, it is thus possible to achieve a miniaturized construction by way of the reflection prism.

The reflection prism is arranged relatively closely to the laser diode, and its entrance surface has a distance of at most 0.5 mm, 0.45 mm, 0.4 mm, 0.35 mm, 0.3 mm, 0.25 mm, 0.2 mm, 0.15 mm, 0.1 mm, 0.09 mm, 0.08 mm or 0.07 mm from its emission surface, e.g. with increasing preference in the order of mention. Possible lower limits can be for example at least 0.0025 mm, 0.003 mm, 0.0035 mm, 0.004 mm, 0.0045 mm or 0.005 mm. Generally, the smallest possible distance may be provided, wherein the lower limit can be based for example on the accuracy of a positioning tool (pick and place tool). Figuratively speaking, by arranging the reflection prism closely to the laser diode, it is being placed in a section of the divergent beam in which the cross section thereof is still relatively small, which permits the desired beam guidance; a beam that has already broadened too widely, on the other hand, could be reflected back to the entrance surface, e.g. partially, cf. also the embodiments for illustration purposes.

The beam has, arranged immediately downstream of the emission surface, a direction component that is parallel to the surface of the carrier structure, e.g. its main direction is parallel thereto, i.e. parallel to a plane that contains the mounting surface of the carrier structure; the “mounting surface” is the region of the laser-diode-facing surface of the carrier structure on which the laser diode is arranged. The laser-diode-facing surface of the carrier structure is preferably planar overall, e.g. with particular preference the carrier structure is a planar plate overall (carrier plate).

Within the context of this disclosure, the main direction of radiation or light generally presents itself as a centroid direction of all direction vectors of the respectively considered beam in the respectively considered section, wherein each direction vector in the case of this average formation is weighted with its associated beam intensity.

After the reflection “away from the carrier structure,” the beam has, arranged immediately downstream of the reflection surface, a direction component perpendicular to the mounting surface, e.g. its main direction is substantially perpendicular thereto. Said main direction can enclose, for example, an angle of at most 30°, 25°, 20°, 15°, 10° or 5° (with increasing preference in the order of mention) with a surface normal on the mounting surface, in the context of typical mounting fluctuations, a propagation parallel to the surface normal can also be preferred (angle of 0°). Within the context of this disclosure, the terms “upstream” or “downstream” generally refer to the path of the beam propagation, taking into consideration its respective propagation direction.

In various embodiments, the active zone of the laser diode, in which the laser radiation is generated, has a distance of at least 0.2 mm from the surface of the carrier structure, e.g. of at least 0.23 mm or 0.26 mm. Accordingly, the emission surface then also has such a distance from the carrier structure, as a result of which slightly more space is available for reflecting the divergently output beam away from the carrier structure. On the other hand, an upper limit can also be specified for the distance between the carrier structure and the active zone, for example for thermal reasons (the greater the distance, the greater the Rₜₕ), and upper limits can be, for example, at most 0.4 mm, 0.35 mm or 0.3 mm (e.g. with increasing preference in the order of mention).

With respect to the configuration of the laser diode, explicit reference is also made to the statements in the citation of the background section. The active zone can have a height, taken perpendicularly to the carrier structure, of around 1 μm; in the surface directions, i.e. parallel to the surface of the carrier structure, the extent is a multiple thereof, for example at least 20 μm, 30 μm, 40 μm or 50 μm, with possible upper limits (independently thereof) for example being at most 300 μm, 250 μm or 200 μm. Independently thereof, the semiconductor layer system of the laser diode may be, for example, an InGaAlP or e.g. an InGaN layer system.

When, within the context of this disclosure, reference is generally made to a “distance” between two elements, this refers to the smallest distance between them. In the case of the emission surface of the laser diode and the entrance surface of the reflection prism, the distance between them can be taken preferably in a direction that is parallel to the surface of the carrier structure, e.g. to the mounting surface. In the case of the active zone, the distance from the carrier structure can be taken e.g. along a surface normal on the mounting surface.

In a configuration, the reflection surface of the reflection prism is planar, i.e. the shape of the beam remains unchanged in the case of the reflection. The planar reflection surface can offer advantages for mounting, for example. As compared to a curved reflection surface, which is generally also feasible, the tolerance with respect to an offset from the ideal position can be increased, i.e. any adjustment complexity is reduced or the construction is less susceptible to manufacturing variations.

In a configuration, the reflection surface encloses an angle of at least 40°, with further and particular preference at least 42° or 44°, with the carrier structure. Possible upper limits, which can generally also be of interest independently of a lower limit (which also applies vice versa), are at most 50°, for example, with further and e.g. at most 48° or 46°. In the context of technically customary accuracies, an angle of 45° may be provided. The angle considered here corresponds to a section angle between two planes, one of which contains the mounting surface (of the carrier structure), and the other contains the reflection surface.

Generally, the entrance and/or the exit surface of the reflection prism, e.g. both, are each planar per se; by way of example, they are perpendicular to one another. The reflection prism may be a 90° reflection prism, the prism material thus has, in cross-sectional view, the form of an isosceles right triangle (with a section plane that is perpendicular to the entrance, reflection and exit surfaces). The respective main direction of the beam may be perpendicular to the entrance and/or the exit surface.

In various embodiments, the entrance surface, e.g. the reflection prism overall, has a height, taken perpendicularly to the carrier structure, of at most 1 mm, e.g. at most 0.9 mm or 0.85 mm. It is possible with a light entrance surface that is correspondingly delimited in terms of height to prevent the problem, described already above, that after reflection, the beam grazes the entrance surface, cf. the embodiment for illustration purposes. Possible lower limits of the height of the reflection prism or of the entrance surface can be, for example, at least 0.6 mm, 0.65 mm, 0.7 mm, or 0.75 mm; boundary conditions are here, for example, the manufacturability of correspondingly small optical structures, or the extent of the reflection surface still being sufficiently large.

In a configuration, the beam has, arranged immediately upstream of the entrance surface, viewed in a section plane which is perpendicular to the carrier structure, an aperture angle of at most 40°, and, e.g. with increasing preference in the order of mention, at most 38°, 36°, 34° or 32°. Possible lower limits can be for example, e.g. with increasing preference in the order of mention, at least 20°, 22°, 24°, 26° or 28°, with upper and lower limits generally also being able to be of interest independently of one another. In the context of this disclosure, generally an extent of the beam is here taken as a basis, which is determined after a power drop to 1/e² (an alternative would be, for example, a drop to ½, i.e. the full width at half maximum).

The laser diode generally emits the beam e.g. with an aperture angle which differs on two axes that are perpendicular with respect to one another and to the main direction, wherein the axis with the greater aperture angle is referred to as the “fast axis,” and the axis having the smaller aperture angle is referred to as the “slow axis”. The fast axis may be perpendicular on the mounting surface, and the slow axis is then parallel with it. The aperture angle information just given thus refers to the fast axis, the aperture angle on the slow axis can be approximately half as large (the installation space limitations discussed in the introduction are relevant on the fast axis). Generally, a “divergent” beam within the meaning of the main claim is already present if the aperture angle is >0° on only one axis perpendicular to the mounting surface.

In various embodiments, the aperture angle of the beam, viewed in a section plane perpendicular to the surface of the carrier structure, decreases upon entry into the reflection prism by at least 30%, with increasing preference in this order at least 35%, 40% or 45% (ultimately also dependent on the refractive index nₚ). Possible upper limits of the decrease can be, independently thereof, for example at most 60%, 55% or 50%. Said section plane is perpendicular on the mounting surface and runs centrally through the beam parallel to the main direction thereof (which also applies to the statements made in the previous paragraph).

In various embodiments, the reflection prism has a wedge-shaped carrier element which is configured in one piece with the prism material, wherein the carrier element is arranged, by its side face that faces away from the prism material, on the carrier plate such that it faces it. The carrier element fills the wedge-shaped space between the carrier structure and the in turn wedge-shaped prism material, and for its wedge angle, the angle values mentioned previously for the angle between the reflection surface and the carrier structure are intended to be disclosed. The carrier element is preferably mirror-symmetric with respect to the prism material, wherein the plane of symmetry coincides with the reflection surface.

As a consequence of the configuration being “in one piece,” the two parts cannot be separated from one another in a destruction-free manner, i.e. not without destroying at least one of the two or destroying a connection layer between them. In various embodiments, a joining connection layer can hold the prism material on the carrier element, e.g. an adhesion layer. The carrier element can be made, for example, of metal or e.g. of silicon, which can simplify the integration in existing mounting processes.

In various embodiments, the laser diode and the reflection prism are arranged on the same contiguous carrier structure, i.e. the carrier structure which is not interrupted between the laser diode and the reflection prism. Within the context of this disclosure, “arranged” may generally be understood to mean mounted, i.e. it refers to the locating and securing of a part which was separately produced previously.

In various embodiments, a dichroic layer system forms the reflection layer of the reflection prism, which can offer effects with respect to efficiency. However, for example a silver layer can generally also form the reflection surface, e.g. if made from highly pure silver. A double layer system, i.e. a combination of a dichroic layer sequence and a metal layer (in particular silver layer) may also be provided, wherein the metal layer is arranged upstream of the dichroic layer system. For example in the case of a reflection prism having a carrier element (see front), for example a dichroic coating can be provided thereon, which is adapted for a reflection of the (blue) laser radiation and thus forms the reflection surface; for example an anti-reflective coating (AR) can then be applied on the transparent prism material toward this reflection surface, likewise adapted for the (blue) laser radiation and for example dichroic.

In various embodiments, an at least translucent, e.g. transparent cover is provided, which is mounted in each case indirectly on the carrier structure. The cover closes off a cavity with the laser diode and the reflection prism inside it in an airtight manner, and the beam exits through the cover downstream of the reflection prism. The air-tightness is provided in accordance with a technical or economically meaningful context; the cavity can be, for example, subject to a vacuum or filled with an inert gas, which can help prevent, for example, the deposition of contaminants or moisture on the emission surface of the laser diode. The cover could generally also be made for example from glass, e.g. is a cover made of sapphire, for example also for thermal reasons.

In a configuration, the at least translucent/preferably transparent cover is mounted on the carrier structure via a metal frame, i.e. the frame carries the cover and is in turn mounted directly on the carrier structure, for example connected thereto by way of a joining connection layer. For the material of the frame, for example copper may be provided. The frame encloses the laser diode and the reflection prism with respect to a perimeter about a surface normal, i.e. it delimits the cavity toward the side. The cover delimits the cavity toward the top.

Within the context of this disclosure, “lateral” generally refers to directions that are parallel to the surface of the carrier structure, whereas “above”/“below” refers to directions that are perpendicular thereto. The side face of the carrier structure having the laser diode is here considered to be the upper side, which generally, however, has no implications with respect to the installation position of the beam source in the application.

In a configuration, the entrance surface of the reflection prism and/or the exit surface of the reflection prism and/or the entrance surface of the cover and/or the exit surface of the cover have an anti-reflective coating. Owing to an anti-reflective coating, the transmittance for the laser radiation is greater on the respective surface than in the case of an uncoated surface. An anti-reflective coating may be implemented by way of a dichroic layer system.

In various embodiments, the beam source has a conversion element, with which the laser radiation is converted, at least in part, into conversion radiation. A down conversion may be provided, i.e. the conversion radiation has a longer wavelength than the laser radiation, e.g. is conversion light in the visible spectral range. The conversion can generally also be a full conversion, in which the entire laser radiation that strikes the conversion element is converted, but a partial conversion may be provided, i.e. arranged downstream of the phosphor element, there is a mixture of conversion radiation and laser radiation that has not been converted in part. It is thus possible, for example, using the blue light as laser radiation, which is generally preferred, to generate white light in mixture with yellow conversion light. The conversion element, which is also referred to as a phosphor element, can have for example yttrium aluminum garnet as the phosphor (YAG:Ce).

The conversion element may be arranged outside the cavity on the cover, even though generally for example an arrangement on the exit surface of the reflection prism is also feasible. The phosphor element can be deposited, for example, on the external surface of the cover, i.e. come into existence only upon application; however, it can also be mounted for example on the cover, for example by way of a joining connection layer, e.g. an adhesion layer, or by way of a low-melting glass solder layer (glass bonding).

Independently thereof, it is possible, e.g. for increasing the efficiency, for a dichroic mirror to be arranged between the cover and the phosphor element, which mirror is transmissive for the laser radiation, but reflective for the conversion radiation.

As already mentioned, the phosphor element can also be deposited on or attached on the exit surface of the reflection prism, either in a directly adjoining fashion or with a layer inbetween. In the latter case, the exit surface of the reflection prism can be provided with a dichroic coating which reflects the (yellow) conversion light and transmits the (blue) excitation light. Alternatively, the dichroic coating which is reflective for the (yellow) conversion light can also be deposited on the entrance side of the conversion element.

In various embodiments, the beam source has a collecting lens, which is arranged on the cover. Generally, the collecting lens could also be integrally formed in the cover, but it may be mounted thereon, specifically on the side face thereof which faces away from the laser diode and the reflection prism. The collecting lens may be configured in the form of a collimation lens, i.e. the beam travels through it, i.e. the beam is still divergent upstream of the collimation lens and is then substantially collimated downstream thereof. The collecting lens can be made, for example, of silicone or glass.

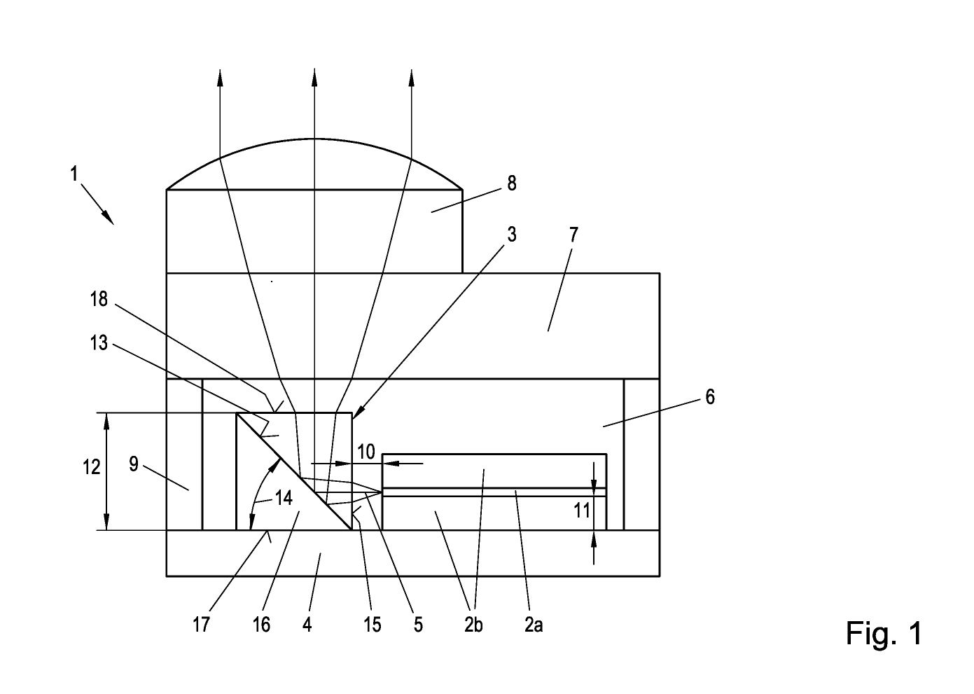

FIG. 1 shows a beam source 1 according to various embodiments having a laser diode 2 and a reflection prism 3, which are mounted on a carrier structure 4. The carrier structure 4 is in the present case a copper plate, the laser diode 2 and the reflection prism 3 are soldered on. The laser radiation is generated in an active zone 2a of the laser diode 2, which is embedded between the remaining semiconductor layers 2b. The active zone 2a has a height of approximately 1 μm, and the laser radiation is emitted in the form of a divergent beam 5.

According to various embodiments, the beam 5 is deflected using the reflection prism 3, and the laser radiation is thus coupled out at the upper side of the construction. For laterally coupling out, however, the carrier structure 4 would, owing to the divergence of the beam 5, have to terminate relatively closely to the laser diode 2 and also have a coupling-out window here. The inventor has determined that the implementation is complicated in mechanical terms and also not very robust, e.g. if the cavity 6 is intended to be closed off in an airtight manner with the laser diode 2 inside.

According to various embodiments, the beam 5 is therefore deflected upwardly using the reflection prism 3. Downstream of the reflection prism 3, it passes through a cover 7 made of sapphire, on the external side of which in the present case a collecting lens 8 is mounted in the form of a collimation lens. However, for example a cover 7 made of glass, on which the collecting lens 8 could be mounted or even be directly pressed against, would also be feasible. On the top side of the cover 5, access is improved owing to a greater distance from the carrier structure 4 and thus also for example from a printed circuit board (not illustrated), on which in turn the carrier structure 4 is arranged. In addition, a lateral delimitation of the cavity 6 also does not have to be configured to be transparent/translucent, but a metal frame 9 can also be mounted on the carrier structure 4. The metal frame 9 carries the cover 7, for example by way of a force fit, and is in turn soldered together with the carrier structure 4, which helps ensure good airtightness of the cavity 6 and thus prevent contamination or compromising of the laser diode 2.

The reflection prism 3 has a glass body made of a prism material having a refractive index of approximately 1.82 (cf. the introduction to the description with respect to further details). Accordingly, the beam 5 upon entry is refracted relatively strongly, i.e. the aperture angle is reduced, and specifically in the case of the present refractive index nearly halved. Owing to this reduction in aperture angle, the beam inside the reflection prism 3 takes up a relatively small space, which permits the miniaturized construction shown.

If the beam 5 were to propagate divergently without being curtailed, however, i.e. if a simple mirror were provided for reflection, it would already generally have a relatively large cross section at the exit of the beam source, which would, for example, also require a correspondingly greater collection lens and would accordingly render the construction more expensive and would also have disadvantages in terms of weight. In addition, a beam 5 which were to propagate at a wide angle without being curtailed, could then, after reflection, slightly graze the laser diode 2. By reducing the aperture angle, on the other hand, the beam 5 can be guided away from the carrier structure 4 well and thus in a region in which the installation space is less limited.

The distance 10 between the reflection prism 3, specifically the entrance surface 15 thereof, and the laser diode 2, specifically the emission surface (not referred to individually for the sake of clarity), is selected to be as small as possible, and is thus in the present case approximately 70 μm. The distance 11 between the carrier structure 4 and the active zone 2a is furthermore also chosen such that, on the one hand, good beam guidance is possible (delimitation toward the bottom), and on the other hand, good thermal bonding is also provided (delimitation toward the top). The distance 11 in the present case is approximately 0.27 mm. The entrance surface 9 or the reflection prism 3 overall has a height 12 of approximately 0.8 mm.

The reflection surface 13 of the reflection prism 3 encloses an angle 14 of 45° with the carrier structure 4. The entrance surface 15 and also an exit surface 18 of the reflection prism 3 are each in themselves planar, they are perpendicular with respect to one another. The reflection prism 3 is a 90° deflection prism. The deflection prism 3 has a carrier element 16 made of silicon, which is configured in one piece with the prism material. The carrier element 16 is, by way of its side face 17 which faces away from the prism material, mounted on the carrier structure 4. Since the carrier element 16 is made of silicon, mounting it can be integrated well into the remaining back-end manufacturing process.

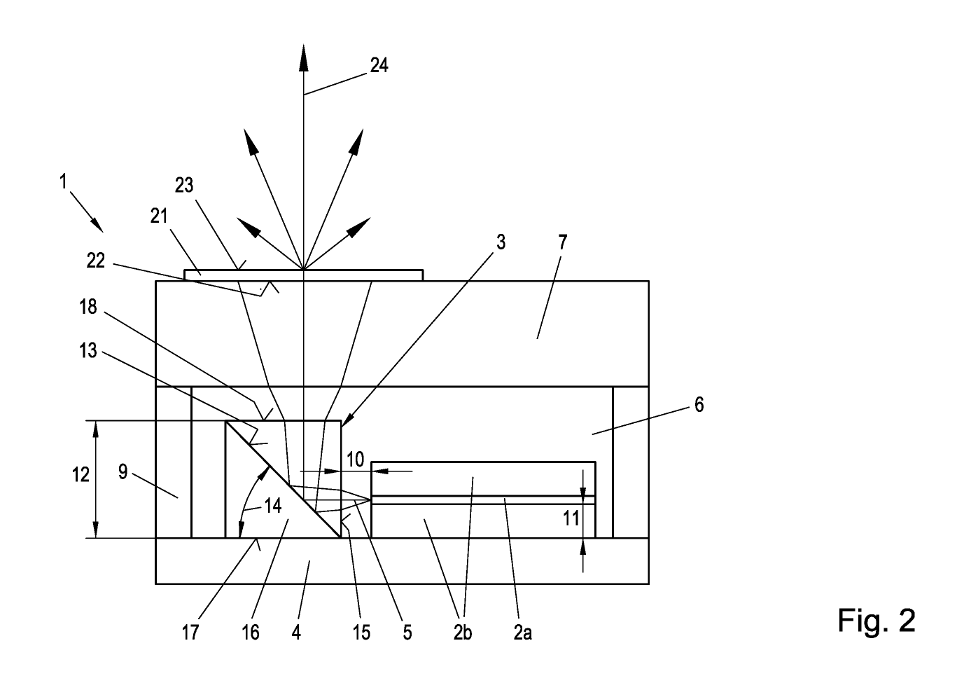

The embodiment according to FIG. 2 is identical to that according to FIG. 1 with respect to the configuration and arrangement of the laser diode 2, reflection prism 3 and also the housing components (carrier structure 4, metal frame 9 and cover 7). However, instead of the collection lens 8, a conversion element 21 is arranged on the cover 7, which has YAG:Ce as the phosphor. The beam 5 with the laser radiation strikes an irradiation surface 22 of the conversion element 21, which, in response to this excitation, emits at an emission surface 23 conversion radiation 24, specifically in the present case yellow conversion light. The laser radiation is blue light, which is not converted completely in the conversion element 21 (partial conversion), and downstream of the phosphor element 21, the laser light which has not been converted in part produces white light in mixture with the conversion radiation 24.

The emission of the conversion radiation 24 is substantially omnidirectional, i.e. conversion radiation would be output also through the cover 7, i.e. downwardly in FIG. 2. In order to increase the efficiency, a dichroic mirror is therefore arranged between the cover 7 and the conversion element 21, which mirror is transmissive for the laser radiation, but reflective for the conversion radiation.

List of Reference Signs

| | |
|---|---|
| beam source | 1 |
| laser diode | 2 |
| active zone thereof | 2a |
| remaining layer system | 2b |
| reflection prism | 3 |
| carrier structure | 4 |
| beam | 5 |
| cavity | 6 |
| cover | 7 |
| collecting lens | 8 |
| metal frame | 9 |
| distance (between emission and entrance surface) | 10 |
| distance (between active zone and carrier structure) | 11 |
| reflection surface | 13 |
| angle | 14 |
| entrance surface (of the reflection prism) | 15 |
| carrier element | 16 |
| side face | 17 |
| exit surface (of the reflection prism) | 18 |
| conversion element | 21 |
| irradiation surface | 22 |
| emission surface | 23 |
| conversion radiation | 24 |

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A beam source, comprising:
a laser diode having an emission surface for emitting a divergent beam with laser radiation;
a carrier structure on which the laser diode is arranged such that the beam has, immediately downstream of the emission surface, a direction component parallel to a surface of the carrier structure that faces the laser diode; and
a reflection prism with a transparent prism material having a refractive index nₚ≧1.5;
wherein the laser diode and the reflection prism are arranged relative to each other such that the beam from the laser diode is incident downstream on an entrance surface of the reflection prism, travels through the prism material with a reduced aperture angle, and in the process is reflected away from the carrier structure at a reflection surface of the reflection prism; and
wherein the emission surface of the laser diode and the entrance surface of the reflection prism have a distance from one another of at most 0.5 mm.

2. The beam source of claim 1,
wherein the laser radiation is generated in an active zone of the laser diode, which has a distance of at least 0.2 mm from the surface of the carrier structure that faces the laser diode.

3. The beam source of claim 1,
wherein the reflection surface of the reflection prism is planar.

4. The beam source of claim 3,
wherein the reflection surface encloses an angle of at least 40° and at most 50° with the carrier structure.

5. The beam source of claim 1,
wherein the entrance surface has a height, taken perpendicularly to the carrier structure, of at most 1 mm.

6. The beam source of claim 1,
wherein the beam has, immediately upstream of the entrance surface of the reflection prism, an aperture angle of at most 40°, taken perpendicularly to the carrier structure.

7. The beam source of claim 1,
wherein an aperture angle of the beam taken perpendicularly to the carrier structure immediately downstream of the entrance surface of the reflection prism is smaller by at least 30% than immediately upstream of the entrance surface.

8. The beam source of claim 1,
wherein the reflection prism has a wedge-shaped carrier element which is configured in one piece with the prism material and is arranged, by a side face that faces away from the prism material, on the carrier structure such that it faces it.

9. The beam source of claim 1,
wherein the laser diode and the reflection prism are arranged on the same contiguous carrier structure.

10. The beam source of claim 1,
wherein a dichroic layer system forms the reflection surface of the reflection prism.

11. The beam source of claim 1,
wherein an at least translucent cover is mounted in each case indirectly on the carrier structure;
wherein the cover closes off a cavity in an airtight manner with the laser diode and the reflection prism therein, and the beam passes through the cover downstream of the reflection prism.

12. The beam source of claim 11, further comprising:
a metal frame which carries the cover and is mounted on the carrier structure such that it encloses the laser diode and the reflection prism and thus delimits the cavity toward the side.

13. The beam source of claim 11,
wherein at least one of the entrance surface of the reflection prism, an exit surface of the reflection prism, an entrance surface of the cover and an exit surface of the cover is coated with an anti-reflective coating.

14. The beam source of claim 11, further comprising:
a collecting lens which is arranged on the cover outside the cavity.

15. The beam source of claim 1, further comprising:
a conversion element for at least partially converting the laser radiation into conversion radiation.
